(19) United States
(12) Patent Application Publication
(10) Pub. No.: US 2026/0122786 A1
(43) Pub. Date: Apr. 30, 2026

(54) SILICON INTERPOSER WITH INTEGRATED VOLTAGE REGULATOR DEVICES AND ASSOCIATED SYSTEMS AND METHODS

(71) Applicant: Micron Technology, Inc., Boise, ID (US)

(72) Inventor: Rajesh H. Kariya, Boise, ID (US)

(21) Appl. No.: 19/338,316

(22) Filed: Sep. 24, 2025

Related U.S. Application Data
(60) Provisional application No. 63/713,705, filed on Oct. 30, 2024.

(51) Int. Cl. H05K 1/18; H01L 25/16; H10B 80/00

(52) U.S. Cl. CPC H05K 1/181; H10B 80/00; H10W 90/00; H05K 2201/10378; H05K 2201/10734

(57) ABSTRACT

Voltage regulator devices on active silicon interposers and associated systems and methods are disclosed. Local High-Bandwidth Memory (HBM) device voltage regulation is provided via the active silicon interposer configured with one or more voltage regulators corresponding to one or more HBM devices of a system-in-package (SiP). Each of the voltage regulators are configured to receive a first voltage signal from an external power supply and to generate one or more voltage signals based on the first voltage signal. The one or more generated voltage signals are supplied to a given HBM device by a locally positioned voltage regulator. In some embodiments, the one or more generated voltage signals are further based on the voltage signal of a sense line coupling a given HBM device to a corresponding voltage regulator.

### CROSS-REFERENCE TO RELATED APPLICATION(S)

The present application claims priority to U.S. Provisional Patent Application No. 63/713,705, filed Oct. 30, 2024, the disclosure of which is incorporated herein by reference in its entirety.

### TECHNICAL FIELD

The present technology is generally related to regulating the voltage of semiconductor devices, and more specifically to systems and methods for interposers with integrated voltage regulators that regulate the voltages of high-bandwidth memory devices and other devices of a system-in-package.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet market demands, such as simplifying circuit design and streamlining operability, can often introduce challenges in other aspects.

### BRIEF DESCRIPTION OF THE DRAWINGS

FIG. 1 is a partially schematic cross-sectional diagram of a system-in-package (SiP) device.

FIG. 2 is a partially schematic cross-sectional diagram of a SiP device.

FIG. 3 is a partially schematic cross-sectional diagram of a SiP device with an active interposer configured in accordance with some embodiments of the present technology.

FIG. 4 is a flow diagram of a process for manufacturing a SiP device in accordance with some embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, lower power consumption, and reduced chip size are features that are demanded from semiconductor memory. In recent years, vertically stacked memory devices have been introduced, often referred to as 2.5-dimensional (“2.5D”) memory devices when placed adjacent to a host device. Some 2.5D memory devices are formed by stacking memory dies vertically, and interconnecting the dies using through-silicon (or through-substrate) vias (TSVs). Benefits of the 2.5D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5D memory devices contribute to higher memory access speed, lower power consumption, and chip size reduction. Example 2.5D memory devices include Hybrid Memory Cube (HMC) and High-Bandwidth Memory (HBM) devices. For example, HBM devices are a type of memory that includes a vertical stack of dynamic random-access memory (DRAM) dies and an interface die (which, e.g., provides the interface between the DRAM dies of the HBM device and a host device). As a further example, HBM devices can include a combination of different volatile and/or non-volatile memory types.

In a system-in-package (SiP) configuration, HBM devices may be integrated with host devices (e.g., one or more graphics processing units (GPUs), computer processing units (CPUs), tensor processing units (TCUs), and/or any other suitable processing units) using a base substrate (e.g., a silicon interposer, a substrate of organic material, a substrate of inorganic material and/or any other suitable material that provides interconnection between the host device and the HBM device and/or provides mechanical support for the components of a SiP device), through which the HBM devices and hosts communicate. Because traffic between the HBM devices and host devices resides within the SiP (e.g., using signals routed through the silicon interposer), a higher bandwidth may be achieved between the HBM devices and host devices than in conventional systems. In other words, the TSVs interconnecting DRAM dies within an HBM device, and the silicon interposer integrating HBM devices and host devices, enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host devices (e.g., GPUs/CPUs/TCUs) and HBM devices during operation. For example, the high-bandwidth channels can be on the order of 1000 gigabytes per second (GB/s, sometimes also referred to as gigabits (Gb)). As a result, the SiP device can quickly complete computing operations once data is loaded into the HBM devices. SiP devices, in turn, are typically integrated with a package substrate (e.g., a PCB) adjacent to other electronics and/or other SiP devices within a packaged system.

Market demands on SiP devices and/or the HBM devices therein can present certain challenges, however. One such challenge arises due to the electrical power needs of SiP devices and components therein (e.g., HBM devices and/or host devices). For example, in some existing configurations, the HBM devices of a SiP receive electrical power from one or more power supplies that are external to the SiP (each an external power supply), where the external power supplies provide power to the HBM devices at multiple power rails (i.e., at different voltage levels and/or ground). Further, each power rail from the external power supply couples to the SiP (e.g., to provide power at that voltage) through an external pin of the SiP substrate, such as a solder ball. Each power rail is provided to the SiP components (e.g., HBM devices) via routing through the substrate and silicon interposer to the target device. Further, in some existing configurations, each power rail may couple to the SiP using multiple external pins (e.g., solder balls) in order to accommodate power and/or amperage requirements, each of which also route to the SiP components. That is, in some cases, hundreds of power connections per HBM device, each requiring a solder ball on the substrate of the SiP, are needed to deliver all of the voltage signals corresponding to the various power rails to each of the HBM devices. Designing SiPs to accommodate so many power connections gives rise to substantial manufacturing and cost challenges that can be particularly limiting as SiPs incorporate greater numbers of HBM devices. Furthermore, the use of a power supply external to the SiP to provide power for the HBM devices and other SiP components at multiple rails can give rise to additional issues, such as relatively slow voltage feedback for voltage correction and/or compensation. That is, it can take a significant amount of time for feedback from an HBM device regarding the voltage level of a received power rail to be received by an external power supply, and for the power rail to be adjusted accordingly, due to the need of a feedback signal to be communicated off the SiP. This correction lag worsens for configurations involving multiple HBM devices sharing a common power supply, as the operation of a given HBM device can impact the voltage correction for the other HBM devices.

The devices, systems, and methods described herein address these and other challenges by providing power, at multiple power rails, to the HBM devices of a SiP via one or more voltage regulators integrated into the silicon interposer of the SiP. As described herein, the silicon interposer with one of more voltage regulators (also referred to herein as an “active silicon interposer”) provides voltage regulation capabilities (e.g., generates one or more voltage signals at multiple voltage rails, from a single supply voltage, for HBM devices of the SiP) that are “local” to the SiP (e.g., the SiP does not rely on voltage regulation performed by off-SiP devices). In some embodiments, each of the voltage regulators of the active silicon interposer are configured to receive a first voltage signal (e.g., a power supply voltage signal) from an external power supply and to generate one or more voltage signals (e.g., a second voltage signal, a third voltage signal, a fourth voltage signal, etc.) corresponding to each of the various power signals for a given HBM device. Thus, the one or more voltage signals used by the one or more HBM devices are generated by one or more voltage regulators that are part of the active silicon interposer on which the HBM devices are carried (i.e., the voltage regulators are local to and/or locally positioned within the SiP). As used herein, said voltage regulators of the active silicon interposer are described as “proximate” or “locally positioned” to an HBM device, in that the voltage regulators are part of the SiP of the HBM devices and therefore are placed physically closer to and have a short communication length between the voltage regulators and the HBM device, as compared to voltage regulators that are part of an external power supply (i.e., off the SiP). Since the voltage signals for the multiple rails needed by the HBM devices (e.g., VDDC, VDDQ, VDDQL, VPP, and ground or GND) are being generated by a locally positioned voltage regulator in the active silicon interposer (which generates the multiple rails from a single voltage provided by an external power supply), rather than from the external power supply, substantially fewer external power connections (e.g., SiP substrate bumps) are needed between the external power supply and the SiP. Specifically, fewer power connections are needed on the external surfaces of the package substrate and fewer power connections are needed between the package substrate and the SiP, since only a source voltage signal for the voltage regulator is needed from the external power supply. This greatly reduces SiP design complexity and associated manufacturing costs. Furthermore, as described further below, this configuration allows for faster voltage sensing and correction, since voltage regulation for each HBM device may occur via one or more voltage regulators in the active silicon interposer, thereby reducing the distance feedback signals need to travel (as compared to sending the feedback off the SiP) and resulting in faster feedback.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

Further, although the active silicon interposer of a SiP is discussed herein primarily in the context of providing power to HBM devices of the SiP (e.g., using the one or more voltage regulators of the active silicon interposer), one of skill in the art will understand that the scope of the technology described herein is not so limited. For example, voltage regulators of the active silicon interposer can provide power to other components of the SiP (such as host devices) instead of and/or in addition to HBM devices of the SiP.

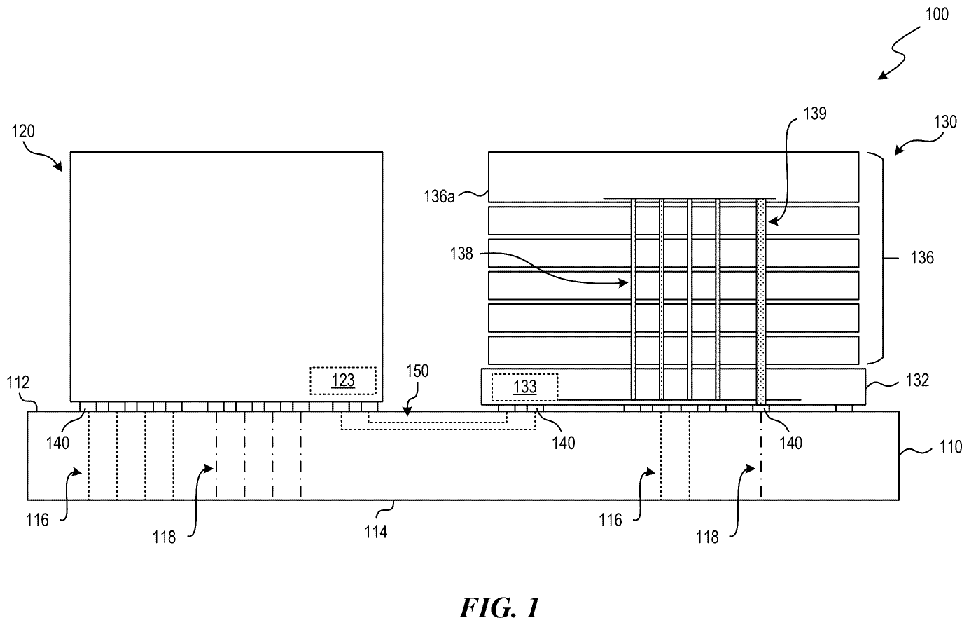

FIG. 1 is a partially schematic cross-sectional diagram of a SiP device 100. As illustrated in FIG. 1, the SiP device 100 includes a base substrate 110 (e.g., a silicon interposer, another organic interposer, an inorganic interposer, and/or any other suitable base substrate), as well as a host device 120 and an HBM device 130 each integrated with (e.g., carried by and coupled to) an upper surface 112 of the base substrate 110 through a plurality of interconnect structures 140 (three labeled in FIG. 1). The interconnect structures 140 can be solder structures (e.g., solder balls), metal-metal bonds, and/or any other suitable conductive structure that mechanically and electrically couples the base substrate 110 to each of the host device 120 and the HBM device 130. Further, the host device 120 is coupled to the HBM device 130 through one or more communication channels 150 formed in the base substrate 110 (sometimes referred to as a SiP bus). The communication channels 150 can include one or more route lines (two illustrated schematically in FIG. 1) formed into (or on) the base substrate 110.

As further illustrated in FIG. 1, the base substrate 110 includes a plurality of external signal TSVs 116 and a plurality of external power TSVs 118 extending between the upper surface 112 and a lower surface 114 of the base substrate 110. The external signal TSVs 116 can communicate signals (e.g., data, control signals, processing commands, and/or the like) between the host device 120 and/or the HBM device 130 and an external component (e.g., a PCB the base substrate 110 is integrated with, an external controller, and/or the like). The external power TSVs 118 provide electrical power to the host device 120 and/or the HBM device 130 from an external power source. For example, the external power source can provide multiple power signals at different voltages (e.g., a first power signal at 1.0 Volt (V), a second power signal at 1.5V, a third power signal at 2.5V, a fourth power signal at 10.0V, etc.). The external power TSVs 118 can be configured to provide each of the multiple power signals and different voltages to the host device 120 and/or HBM device 130.

The host device 120 can include a variety of components, such as a processing unit (e.g., CPU/GPU/TCU), one or more registers, one or more cache memories, and/or a variety of other components. For example, in the illustrated environment, the host device 120 includes a host IO circuit 123 that can direct signals to and/or from the HBM device 130 through the communication channels 150. Additionally, or alternatively, the host IO circuit 123 can direct signals to and/or from an external component (e.g., a controller coupled to one or more of the external signal TSVs 116 and/or the like).

The HBM device 130 can include an interface die 132 and a stack of one or more memory dies 136 (six illustrated in FIG. 1) carried by the interface die 132. The HBM device 130 also includes one or more signal TSVs 138 (four illustrated in FIG. 1) and one or more power TSVs 139 (one illustrated in FIG. 1) each extending from the interface die 132 to an uppermost memory die 136a. The power TSV(s) 139 provide power (e.g., received from one or more of the external power TSVs 118) to the interface die 132 and each of the memory dies 136. The signal TSVs 138 communicably couple each of the memory dies 136 to an IO circuit 133 in the interface die 132 (in addition to various other circuits in the interface die 132). In turn, the IO circuit 133 can direct signals to and/or from the host device 120 and/or an external component (e.g., an external storage device coupled to one or more of the external signal TSVs 116 and/or the like). As illustrated in FIG. 1, the HBM device 130 includes a single IO circuit 133 disposed on a single side of the interface die 132. In further examples, multiple IO circuits can be disposed on multiple sides of the interface die 132.

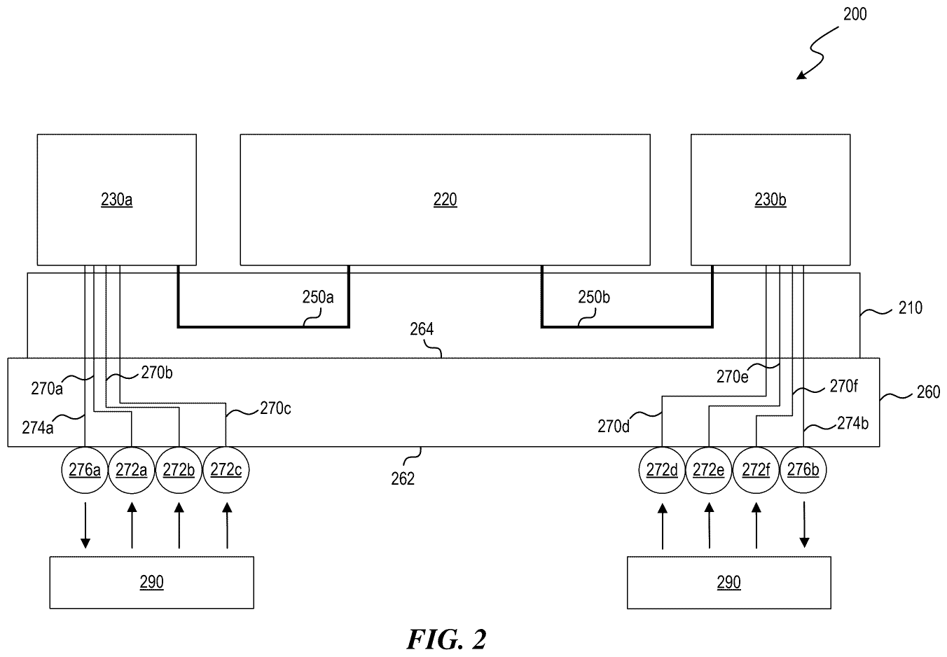

FIG. 2 is a partially schematic cross-sectional diagram of a SiP device 200. In some embodiments, the SiP device 200 includes similar components and features as the SiP device 100 of FIG. 1. Accordingly, like reference numbers refer to like components and features.

SiP device 200 includes a first HBM device 230a and a second HBM device 230b. The first HBM device 230a is communicably coupled to a host device 220 via a first communication channel 250a, and the second HBM device 230b is communicably coupled to the host device 220 via a second communication channel 250b. The HBM devices 230a, 230b, and host device 220, are carried by a base substrate 210, such as a silicon interposer. The base substrate 210 is carried by a package substrate 260, such as a PCB. The package substrate 260 includes a first surface 262 (e.g., an external surface and/or a lower surface) and a second surface 264 (e.g., an interior surface and/or an upper surface). The base substrate 210 contacts the package substrate 260 at the second surface 264.

The SiP device 200 is configured to receive multiple power signals 270a-f (i.e., power rails, voltage signals) from an external power source 290. Because the external power source 290 is off-SiP, each of the power signals 270a-f is provided to the SiP device 200 via a corresponding power connection 272a-f (e.g., solder balls, metal-to-metal interconnections, etc.) coupled to the first surface 262 of the package substrate 260. For example, first, second and third voltage signals 270a, 270b, and 270c (e.g., VDDC, VDDQ, VDDQL, VPP) corresponding to different voltages (e.g., 1.0V, 1.3V, 1.5V, 2.0V, etc.) are supplied to the first HBM device 230a via first, second and third solder balls 272a, 272b, 272c, respectively. Fourth, fifth, and sixth voltage signals 270d, 270e, and 270f are supplied to the second HBM device 230b via fourth, fifth, and solder balls 272d, 272e, and 272f, respectively.

In some embodiments, SiP device 200 includes first and second sense lines 274a, 274b, corresponding to (i.e., generated by) the first and second HBM devices 230a, 230b, respectively. The first and second sense lines 274a, 274b characterize the voltage drop between the external power source 290 and the first and second HBM devices 230a, 230b. For example, the first and second sense lines 274a, 274b can be non-current-carrying connections between the first and second HBM devices 230a, 230b, and the external power source 290. The first and second sense lines 274a, 274b provide voltage feedback and/or compensation of the voltage signals provided from the external power source 290 to the first and second HBM devices 230a, 230b. The first and second sense lines 274a, 274b, connect to the external power source 290 via corresponding first and second sense line interconnections 276a, 276b (e.g., solder balls, metal-to-metal interconnections, etc.), which are coupled to the first surface 262 of the package substrate 260.

Although FIG. 2 illustrates two instances of the external power source 290, in some systems, a single external power source 290 is used to supply power to multiple HBM devices on a SiP. That is, the external power source 290 is shared by multiple HBM devices (e.g., first and second HBM devices 230a, 230b). In such systems, voltage correction of a given HBM device (e.g., the first HBM device 230a) can impact the voltage correction of other HBM devices (e.g., the second HBM device 230b) sharing the external power source 290. This can be particularly challenging if, for example, the first HBM device 230a needs more voltage and the second HBM device 230b needs less voltage, since raising the source voltage to accommodate the first HBM device 230a may also raise the voltage received by the second HBM device 230b.

Devices, methods, and systems for a SiP device comprising one or more HBM devices carried by an active silicon interposer are disclosed. The active silicon interposer is carried by a package substrate with a first surface and a second surface opposite the first surface. At least one solder ball is coupled to the first surface of the package substrate and is configured to receive a voltage signal from an external power supply. The active silicon interposer is positioned on the second surface of the package substrate, and includes (e.g., as part of the interposer structure) one or more voltage regulators corresponding to (i.e., provides voltage signals to) one or more HBM devices (e.g., a first voltage regulator corresponds to a first HBM device, a second voltage regulator corresponds to a second HBM device, etc.). In some embodiments, a given voltage regulator corresponds to (i.e., provides voltage signals to) multiple HBM devices (e.g., a first voltage regulator corresponds to first and second HBM devices). In some embodiments, multiple voltage regulators correspond to a given HBM device (e.g., first and second voltage regulators correspond to a first HBM device). In some embodiments, each of the voltage regulators is locally positioned to the corresponding HBM device. For example, the first voltage regulator can be positioned in an area of the active silicon interposer directly adjacent (e.g., below) the first HBM device, and the second voltage regulator can be positioned in an area of the active silicon interposer directly adjacent the second HBM device.

Each of the voltage regulators is configured to receive a voltage signal from an external power supply (e.g., via the solder balls coupled to the first surface of the package substrate) and to generate one or more voltage signals based on the received voltage signal. Each of the generated voltage signals is supplied to and received by a power supply input/output (IO) circuit for the corresponding HBM device. For example, a first voltage regulator can be configured to receive a first voltage signal from a 10-12V power supply via a first solder ball (and/or first plurality of solder balls) of the package substrate, and to generate second and third voltage signals based on the first voltage signal. The second and third voltage signals are received by a power supply IO circuit of a first HBM device. Further, a second voltage regulator can be configured to receive a fourth voltage signal from the 10-12V power supply via a second solder ball (and/or second plurality of solder balls) of the package substrate, and to generate fifth, sixth, and seventh voltage signals based on the fourth voltage signal. The fifth, sixth, and seventh voltage signals are received by a power supply IO circuit of a second HBM device. In some embodiments, a voltage regulator of the active silicon interposer is coupled to the external power supply via multiple solder balls, all of which are used to provide a voltage signal at the same voltage level (e.g., 10V). In some embodiments, a voltage regulator of the active silicon interposer is coupled to the external power supply via a single solder ball.

In some embodiments, the voltage regulator generates one or more voltage signals that are the same voltage as the voltage signal received from the external power supply. In some embodiments, the voltage regulator generates one or more voltage signals that are a different voltage from the voltage signal received from the external power supply. For example, a voltage regulator can receive a 10V signal from an external power supply, based on which the voltage regulator can generate voltage signals at 10V, 1.0V, 1.5V, and/or 2.5V. In some embodiments, the external power supply generates and supplies different voltage signals to the one or more voltage regulators. For example, the external power supply can generate and supply a first voltage signal of 10V to the first voltage regulator, and can generate and supply a second voltage signal of 12V to the second voltage regulator. In some embodiments, each of the voltage regulators receives voltage signals of the same voltage from the external power supply.

In some embodiments, the SiP is comprised of a voltage feedback mechanism for localized voltage regulation of the HBM devices. In some embodiments, one or more of the HBM devices can generate a sense line that is received by the corresponding voltage regulator, and which characterizes the voltage drop between the HBM device and the corresponding voltage regulator. For example, the sense line can be a non-current carrying connection between the HBM device and the corresponding voltage regulator. The corresponding voltage regulator can modify one or more of the voltage signals generated by the voltage regulator in response to the voltage of the sense line (e.g., adjust a generated voltage signal to have an increased or decreased voltage level, based on the feedback from the sense line).

In some embodiments, the SiP is comprised of a direct access (DA) feature to facilitate external modification of one or more of the voltage signals generated by the voltage regulator. For example, a DA line can be coupled to a DA solder ball of the package substrate and a first voltage regulator. The first voltage regulator can be configured to receive a first voltage signal from an external power supply and to generate a second voltage signal based on the first voltage signal. The DA line can be configured to receive input from a source external the SiP via the DA solder ball, and can modify the second voltage signal of the first voltage regulator based on the received input.

In some embodiments, the voltage regulators can be configured to optimize or “tune” the power and performance characteristics of the corresponding HBM devices (e.g., to compensate for silicon differences of HBM devices). In such embodiments, each of the power supply IO circuits of each of the HBM devices is comprised of a power IO port configured to receive a power signal corresponding to a baseline voltage. For example, a power supply IO circuit for a first HBM device can be comprised of a first power IO port, and a power supply IO circuit for a second HBM device can be comprised of a second power IO port. The first and second power IO ports can be configured to receive power signals corresponding to a baseline voltage. In some embodiments, the baseline voltage is the same for the first and second power IO ports. In some embodiments, the baseline voltage of the first power IO port is different from the baseline voltage of the second power IO port.

The power IO ports are coupled to one or more of the voltage signals generated by the associated voltage regulator. For example, a first voltage regulator associated with a first HBM device can receive a first voltage signal from an external power supply and generate a second voltage signal based on the first voltage signal. The first power IO port of the first HBM device can be coupled to the second voltage signal. In one example of optimizing power and/or performance, the first voltage regulator can generate the second voltage signal with a voltage greater than the baseline voltage the first power IO port is configured to receive. Accordingly, the first HBM device receives a greater power signal than the baseline voltage (e.g., at a power IO port with a baseline voltage of 1.5V, it receives a voltage signal of 1.7V), which can impact power and performance characteristics of the HBM device (e.g., increased operating speed and increased power consumption). Additionally, a second voltage regulator associated with a second HBM device can receive a third voltage signal from the external power supply and generate a fourth voltage signal based on the third voltage signal. The second power IO port of the second HBM device can be coupled to the fourth voltage signal. In another example of optimizing power and/or performance, the second voltage regulator can generate the fourth voltage signal with a voltage less than the baseline voltage the second power IO port is configured to receive (e.g., at a power IO port with a baseline voltage of 1.0V, it receives a voltage signal of 0.8V). Accordingly, the second HBM device receives a reduced power signal than corresponds with the baseline voltage, which can reduce run speed and power consumption. In some embodiments, the voltage signals provided by the voltage regulators to the corresponding power IO ports are the same as the baseline voltages, in which case there is no associated impact (increase or decrease) on power and performance characteristics.

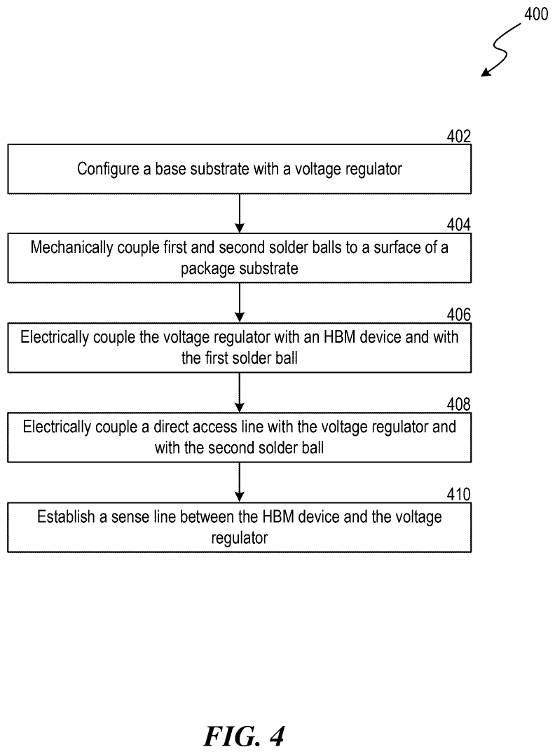

In some embodiments, tuning of the HBM devices occurs during SiP assembly and/or manufacturing. For example, when configuring a base substrate with a voltage regulator (e.g., discussed in block 402 of FIG. 4), the voltage regulator can be configured to generate voltage signals greater than and/or less than the baseline voltage of the corresponding power IO port. In some embodiments, the tuning of the HBM devices occurs dynamically (e.g., after manufacture) via an external input provided to the voltage regulators, such as via the DA line discussed herein.

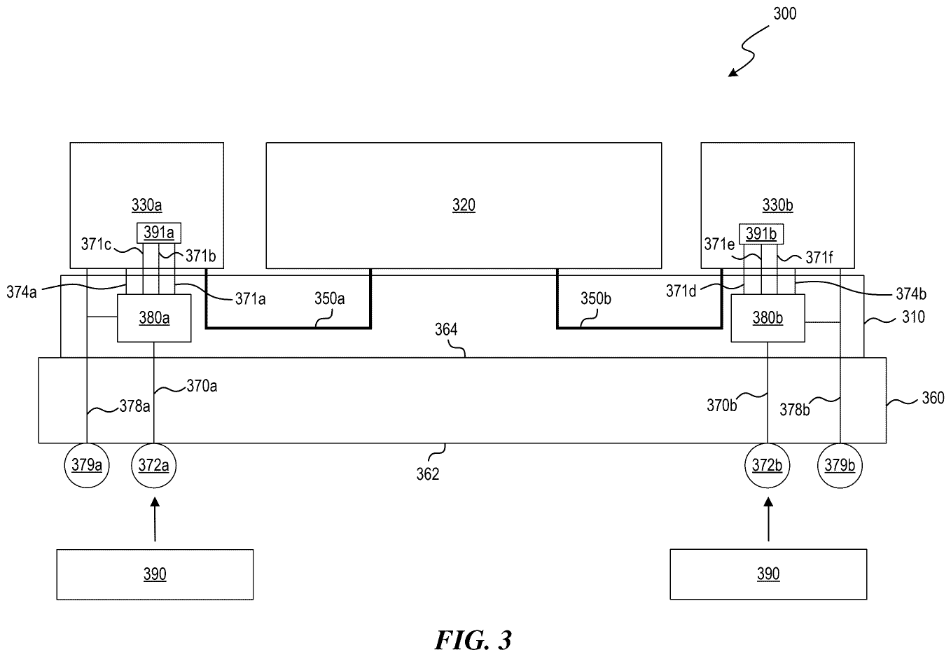

Additional details on the SiP device, active silicon interposer, components thereof, and related systems and methods are discussed below with reference to FIGS. 3-4.

FIG. 3 is a partially schematic cross-sectional diagram of a SiP device 300 with an active silicon interposer 310 configured in accordance with some embodiments of the present technology. In some embodiments, SiP device 300 includes features and components generally similar/identical to the features and components of SiP device 100 of FIG. 1 and/or SiP device 200 of FIG. 2. Accordingly, like reference numbers refer to like features and components.

In the present embodiment, SiP device 300 is comprised of first and second HBM devices 330a, 330b communicably coupled to a host device 320 via first and second communication channels 350a, 350b, respectively. Each of the HBM devices 330a, 330b, is carried by active silicon interposer 310. The active silicon interposer 310 is carried by package substrate 360 with a first surface 362 and a second surface 364 opposite the first surface 362. First and second solder balls 372a, 372b, are coupled to the first surface 362 of the package substrate 360. The first and second solder balls 372a, 372b are configured to receive a voltage signal from an external power supply/source 390. In some embodiments, the first and second solder balls 372a, 372b are part of first and second sets and/or pluralities of solder balls, respectively. In some embodiments, each of the first and second sets of solder balls is no greater than: 400 solder balls, 300 solder balls, 200 solder balls, 100 solder balls, 70 solder balls, 60 solder balls, 50 solder balls, 40 solder balls, and/or 30 solder balls. The active silicon interposer 310 is positioned on and/or in contact with the second surface 364 of the package substrate 360. The active silicon interposer 310 is comprised of first and second voltage regulators 380a, 380b. In some embodiments, the first voltage regulator 380a corresponds with (i.e., provides voltage signals to) and is proximate to the first HBM device 330a, and the second voltage regulator 380b corresponds with and is proximate to the second HBM device 330b. That is, the first voltage regulator 380a is positioned in an area of the active silicon interposer 310 adjacent (e.g., below) the first HBM device 330a, and the second voltage regulator 380b is positioned in an area of the active silicon interposer 310 adjacent the second HBM device 330b. Although FIG. 2 illustrates an embodiment in which the active silicon interposer 310 includes two voltage regulators (first voltage regulator 380a and second voltage regulator 380b), it will be appreciated that in embodiments the active silicon interposer 310 may have more or fewer voltage regulators. Further, in some embodiments the active silicon interposer 310 can include a voltage regulator that provides voltages to more than one HBM device.

The first voltage regulator 380a is configured to receive a first voltage signal 370a from external power source 390 via the first solder ball 372a, and to generate a second voltage signal 371a based on the first voltage signal 370a. In some embodiments, the first voltage regulator 380a is further configured to generate third and fourth voltage signals 371b, 371c based on the first voltage signal 370a. For example, the first voltage regulator 380a can receive a first voltage signal 370a of 10V from the external power source 390 and generate a second voltage signal 371a of 1.5V, a third voltage signal 371b of 2.0V, and a fourth voltage signal 371c of 2.5V. The first voltage regulator 380a supplies the second, third, and fourth voltage signals 371a-c to the first HBM device 330a. In some embodiments, the first voltage regulator 380a is configured to supply the generated voltage signals (e.g., voltage signals 371a-c) to a first power supply IO circuit 391a of the first HBM device 330a.

The second voltage regulator 380b is configured to receive a voltage signal 370b (e.g., a fifth voltage signal) from external power source 390 via the second solder ball 372b, and to generate voltage signals 371d-f based on the voltage signal 370b. For example, the second voltage regulator 380b can receive a fifth voltage signal 370b of 12V from the external power source 390 and generate a sixth voltage signal 371d of 12V, a seventh voltage signal 371e of 2.5V, and an eight voltage signal 371f of 1.5V. The second voltage regulator 380b supplies the voltage signals 371d-f to the second HBM device 330b. In some embodiments, the second voltage regulator 380b is configured to supply the generated voltage signals (e.g., voltage signals 371d-f) to a second power supply IO circuit 391b of the second HBM device 330b.

In some embodiments, the first and second voltage regulators 380a, 380b are configured to tune the power and performance characteristics of the first and second HBM devices 330a, 330b respectively. In such embodiments, the first and second power supply IO circuits 391a, 391b are comprised of first and second power IO ports, respectively. The first and second power IO ports are configured to receive a power signal corresponding to a baseline voltage. For example, the first power supply IO circuit 391a can be configured to receive a power signal corresponding to a first baseline voltage, and the second power supply IO circuit 391b can be configured to receive a power signal corresponding to a second baseline voltage different from the first baseline voltage. In some embodiments, the first and second baseline voltages are the same voltages.

In some embodiments, the first power supply IO circuit 391a (and corresponding first power IO port) is coupled to one or more of the voltage signals 371a-c generated by the first voltage regulator 380a. In some embodiments, one or more of the voltage signals 371a-c are greater than the first baseline voltage, resulting in a corresponding increase in power and performance characteristics (e.g., operating speed, power consumption, etc.) for the first HBM device 330a. In some embodiments, the second power supply IO circuit 391b (and corresponding second power IO port) is coupled to one or more of the voltage signals 371d-f generated by the second voltage regulator 380b. In some embodiments, one or more of the voltage signals 371d-f are greater than the second baseline voltage, resulting in a corresponding increase in power and performance characteristics for the second HBM device 330b. In some embodiments, the first voltage regulator 380a supplies one or more voltage signals 371a-c that are less than the first baseline voltage, and the second voltage regulator 380b supplies one or more voltage signals 371d-f that are less than the second baseline voltage, resulting in corresponding decreases in power and performance characteristics for each of the first and second HBM devices 330a, 330b. In some embodiments, the first voltage regulator 380a supplies one or more voltage signals 371a-c that are greater than the first baseline voltage, and the second voltage regulator 380b supplies one or more voltage signals 371d-f that are less than the second baseline voltage. In some embodiments, the first voltage regulator 380a supplies one or more voltage signals 371a-c that are at least approximately the same as the first baseline voltage, and the second voltage regulator 380b supplies one or more voltage signals 371d-f that are different than the second baseline voltage.

In some embodiments, each of the first and second HBM devices 330a, 330b is configured with a local voltage feedback mechanism via the first and second voltage regulators 380a, 380b, respectively. In some embodiments, the first HBM device 330a is configured to generate a first sense line 374a that is received by the first voltage regulator 380a. The first voltage regulator 380a is configured to modify one or more of the voltage signals 371a-c based on a voltage of the first sense line 374a. In some embodiments, the second HBM device 330b is configured to generate a second sense line 374b that is received by the second voltage regulator 380b. The second voltage regulator 380b is configured to modify one or more of the voltage signals 371d-f based on a voltage of the second sense line 374b. Due to the relatively close proximity of the first and second voltage regulators 380a, 380b to the first and second HBM devices 330a, 330b, respectively, as compared to systems in which the voltage regulators are external to the SiP (and interposer therein), voltage feedback is comparatively fast relative to voltage feedback via the remotely-located external power source 390. Additionally, since the first and second HBM devices 330a, 330b receive voltage signals from separate voltage regulators, voltage compensation for one HBM device (e.g., the first HBM device 330a) is relatively unaffected by voltage compensation for the other HBM device (e.g., the second HBM device 330b), compared to voltage compensation from a common external power source (e.g., external power source 390). For example, if the first HBM device 330a needs more voltage and the second HBM device 330b needs less voltage, the first voltage regulator 380a can modify (i.e., increase) the voltage of one or more voltage signals 371a-c to accommodate the first HBM device 330a without affecting the voltage of the voltage signals 371d-f received by the second HBM device 330b. Likewise, the second voltage regulator 380b can decrease the voltage of one or more voltage signals 371d-f to accommodate the second HBM device 330b without affecting the voltage of the voltage signals 371a-c received by the first HBM device 330a.

In some embodiments, the SiP device 300 is comprised of a first direct access (DA) line 378a to facilitate external modification of the voltage signals 371a-c generated by the first voltage regulator 380a, and a second DA line 378b to facilitate external modification of the voltage signals 371d-f generated by the second voltage regulator 380b. In some embodiments, the first DA line 378a is coupled to the first voltage regulator 380a, and a first DA solder ball 379a. The first DA solder ball 379a is coupled to the first surface 362 of the package substrate 360 and is configured to receive input from a source (not pictured) external to the SiP device 300. The first DA line 378a is configured to receive input via the first DA solder ball 379a, and is configured to modify one or more of the voltage signals 371a-c generated by the first voltage regulator 380a based on the received input. In some embodiments, the second DA line 378b is coupled to the second voltage regulator 380b, and a second DA solder ball 379b. The second DA solder ball 379b is coupled to the first surface 362 of the package substrate 360 and is configured to receive input from a source external the SiP device 300. The second DA line 378b is configured to receive input via the second DA solder ball 379b, and is configured to modify one or more voltage signals 371d-f generated by the second voltage regulator 380b based on the received input.

FIG. 4 is a flow diagram of a process 400 for manufacturing a SiP device in accordance with some embodiments of the present technology. The process 400 can be implemented by a single manufacturing apparatus and/or split between multiple manufacturing apparatuses to construct SiP devices according to the embodiments discussed above.

The process 400 begins at block 402 by configuring a base substrate with a voltage regulator. For example, a silicon interposer can be configured with a voltage regulator integrated with the silicon interposer. In some embodiments, the base substrate is configured to carry one or more HBM devices (such as any of the HBM devices described with reference to FIGS. 1-3) and a host device. In some embodiments, the base substrate is carried by a package substrate, such as a PCB. The voltage regulator is configured to receive a voltage signal from an external power source, generate one or more voltage signals based on the received voltage signal, and supply the generated voltage signals to an HBM device. In some embodiments, the voltage regulator is positioned in an area proximate an HBM device, where the HBM device is configured to receive one or more voltage signals generated by the voltage regulator. In some embodiments, the voltage regulator is configured to tune and/or optimize power and performance characteristics of the HBM device. In such embodiments, the voltage regulator is configured to generate voltage signals greater than and/or less than a baseline voltage of the HBM device.

At block 404, first and second solder balls are mechanically coupled to a surface of a package substrate. In some embodiments, the first and second solder balls are mechanically coupled (e.g., welded) to an external surface of a substrate, where the external surface is opposite an internal surface of the substrate. The internal surface is configured to carry and be in contact with the base substrate. In some embodiments, the first and second solder balls are part of first and second sets and/or pluralities of solder balls, respectively. In some embodiments, the first solder ball is configured to receive a voltage signal from an external power source and to provide the voltage signal to the voltage regulator. In some embodiments, the second solder ball is configured to receive an external input (i.e., an external voltage signal) and to provide the external input to a direct access (DA) line.

At block 406, the voltage regulator is electrically coupled to an HBM device and the first solder ball. In some embodiments, the HBM device is carried by the base substrate. In some embodiments, the HBM device is positioned on a part of the base substrate proximate to the voltage regulator (e.g., directly above and/or adjacent to the voltage regulator). At block 408, a DA line is electrically coupled to the voltage regulator and the second solder ball. The DA line is configured to provide an external voltage signal to the voltage regulator via the second solder ball. In some embodiments, the voltage regulator is configured to modify one or more of the voltage signals generated by the voltage regulator based on the external voltage signal provided by the DA line.

At block 410, a sense line is established between the HBM device and the voltage regulator. In some embodiments, the sense line is generated by the HBM device. In some embodiments, the voltage regulator is configured to modify one or more of the voltage signals generated by the voltage regulator based on a voltage of the sense line.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately,” “generally,” and/or “about” are used herein to mean within at least 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (SiP) device configured with local voltage regulation, the SiP device comprising:
a package substrate comprising:
a first surface;
a second surface opposite the first surface; and
at least one solder ball coupled to the first surface, the at least one solder ball configured to receive a first voltage signal supplied by an external power supply;
an active silicon interposer carried by the package substrate and positioned on the second surface of the package substrate, the active silicon interposer comprising:
a voltage regulator configured to:
receive the first voltage signal from the external power supply via the at least one solder ball; and
generate a second voltage signal based on the first voltage signal; and
a high-bandwidth memory (HBM) device carried by the active silicon interposer, the HBM device comprising:
an interface die comprising a power supply input/output (IO) circuit, the power supply IO circuit configured to receive the second voltage signal generated by the voltage regulator; and
one or more volatile memory dies carried by the interface die.

2. The SiP device of claim 1, wherein the second voltage signal generated by the voltage regulator and the first voltage signal are a same voltage.

3. The SiP device of claim 1, wherein the second voltage signal generated by the voltage regulator is a different voltage from the first voltage signal.

4. The SiP device of claim 1, wherein the voltage regulator is further configured to generate a third voltage signal based on the first voltage signal, the third voltage signal being a different voltage than the second voltage signal, and wherein the power supply IO circuit of the HBM device is further configured to receive the third voltage signal generated by the voltage regulator.

5. The SiP device of claim 1, further comprising a sense line, the sense line generated by the HBM device and received by the voltage regulator, wherein the voltage regulator is further configured to modify the second voltage signal in response to a voltage of the sense line.

6. The SiP device of claim 1, further comprising a direct access (DA) line coupled to a solder ball of the package substrate and the voltage regulator, the voltage regulator further configured to modify the second voltage signal based on input from the DA line.

7. The SiP device of claim 1, further comprising:
a second solder ball coupled to the first surface of the package substrate, the second solder ball configured to receive a third voltage signal supplied by the external power supply;
a second voltage regulator of the active silicon interposer, the second voltage regulator configured to:
receive the third voltage signal from the external power supply via the second solder ball; and
generate a fourth voltage signal based on the third voltage signal; and
a second HBM device carried by the active silicon interposer, the second HBM device configured to receive the third voltage signal generated by the second voltage regulator.

8. The SiP device of claim 7, wherein the first voltage signal generated by the external power supply and the third voltage signal generated by the external power supply are a same voltage.

9. The SiP device of claim 7, wherein the first voltage signal generated by the external power supply and the third voltage generated by the external power supply are different voltages.

10. The SiP device of claim 7, wherein the second voltage signal generated by the first voltage regulator and the fourth voltage signal generated by the second voltage regulator are a same voltage.

11. The SiP device of claim 7, wherein the second voltage signal generated by the first voltage regulator and the fourth voltage signal generated by the second voltage regulator are different voltages.

12. The SiP device of claim 7, wherein the first, second, third, and fourth voltage signals are each different voltages from each other.

13. The SiP device of claim 7, wherein the power supply IO circuit for the first HBM device comprises a first power IO port, the power supply IO circuit for the second HBM device comprises a second power IO port, and both the first power IO port and second power IO port are configured to receive a power signal corresponding to a baseline voltage, and wherein:
the first power IO port is coupled to the second voltage signal, the second voltage signal associated with a voltage different from the baseline voltage; and
the second power IO port is coupled to the fourth voltage signal, the fourth voltage signal associated with a voltage different from the baseline voltage.

14. The SiP device of claim 13, wherein the second voltage signal is less than the baseline voltage, and wherein the fourth voltage signal is less than the baseline voltage.

15. The SiP device of claim 13, wherein the second voltage signal is greater than the baseline voltage, and wherein the fourth voltage signal is greater than the baseline voltage.

16. The SiP device of claim 13, wherein the second voltage signal is greater than the baseline voltage, and wherein the third voltage signal is less than the baseline voltage.

17. The SiP device of claim 1, further comprising a host device carried by the active silicon interposer, the host device positioned adjacent to the first HBM device and communicably coupled to the first HBM device.

18. An HBM voltage regulation device comprising:
a printed circuit board (PCB) comprising at least one solder ball, the at least one solder ball configured to receive a first voltage signal supplied by an external power supply; and
an active silicon interposer carried by the PCB, the active silicon interposer comprising:
a voltage regulator configured to:
receive the first voltage signal from the external power supply via the at least one solder ball;
generate a second voltage signal based on the first voltage signal;
supply the second voltage signal to an HBM device;
receive a voltage from a sense line generated by the HBM device; and
modify the second voltage signal based on the voltage of the sense line.

19. The HBM voltage regulation device of claim 18, wherein the voltage regulator is further configured to generate a third voltage signal based on the first voltage signal, the third voltage signal being a different voltage than the second voltage signal, and wherein the voltage regulator is further configured to supply the third voltage signal to the HBM device.

20. The HBM voltage regulation device of claim 18, further comprising:
a second solder ball of the PCB configured to receive a third voltage signal supplied by the external power supply; and
a second voltage regulator of the active silicon interposer, the second voltage regulator configured to:
receive the third voltage signal from the external power supply via the second solder ball;
generate a fourth voltage signal based on the third voltage signal;
supply the fourth voltage signal to a second HBM device;
receive a voltage from a sense line generated by the second HBM device; and
modify the fourth voltage signal based on the voltage of the sense line.
